(19) United States
(12) Patent Application Publication
(10) Pub. No.: US 2026/0247768 A1
(43) Pub. Date: Aug. 20, 2026

(54) INTEGRATED THERMAL THROTTLING IN LIGHT-EMITTING DIODE CHIPS AND PACKAGES

(71) Applicant: CreeLED, Inc., Durham, NC (US)

(72) Inventors: Tucker McFarlane, Cary, NC (US); Austin Spencer, Durham, NC (US); Thomas Celano, Cary, NC (US); F James Claire, Chapel Hill, NC (US); Colin Blakely, Raleigh, NC (US); Joseph G. Sokol, Durham, NC (US)

(21) Appl. No.: 19/055,981

(22) Filed: Feb. 18, 2025

(51) Int. Cl. H10H 20/858; H10H 20/832; H10H 20/85; H01C 7/04

(52) U.S. Cl. CPC H10H 20/8585; H10H 20/832; H10H 20/8508; H01C 7/04

(57) ABSTRACT

Light-emitting diode (LED) devices and more particularly integrated thermal throttling in LED chips and LED packages are disclosed. Thermal throttling devices are integrated as part of electrically conductive pathways within LED chips and/or within LED packages. When temperature conditions rise above certain thresholds, integrated thermal throttling devices reduce and/or halt current flow, thereby avoiding overheating of LED chips and LED packages. Thermal throttling devices may be positioned proximate anode and/or cathode pads at a chip-level and/or proximate anode and/or cathode connections at a package-level. With such integration, LED chips and LED packages may exhibit self-protection against excess temperature operating conditions.

### FIELD OF THE DISCLOSURE

The present disclosure relates to light-emitting diode (LED) devices, and more particularly to integrated thermal throttling in LED chips and packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to integrated thermal throttling in LED chips and LED packages. Thermal throttling devices are integrated as part of electrically conductive pathways within LED chips and/or within LED packages. When temperature conditions rise above certain thresholds, integrated thermal throttling devices reduce and/or halt current flow, thereby avoiding overheating of LED chips and LED packages. Thermal throttling devices may be positioned proximate anode and/or cathode pads at a chip-level and/or proximate anode and/or cathode connections at a package-level. With such integration, LED chips and LED packages may exhibit self-protection against excess temperature operating conditions.

In one aspect, an LED chip comprises: an active LED structure; an anode pad and a cathode pad on the active LED structure; and a thermal throttling device on the active LED structure and electrically coupled to the anode pad or the cathode pad, the thermal throttling device being configured to have a resistance that changes based on a temperature of the thermal throttling device. In certain embodiments, the thermal throttling device is configured to reduce current flow through the LED chip when the temperature reaches a threshold temperature. In certain embodiments, the thermal throttling device is positioned between the active LED structure and either the anode pad or the cathode pad. In certain embodiments, the thermal throttling device is a first thermal throttling device positioned between the active LED structure and the anode pad, and a second thermal throttling device is positioned between the active LED structure and the cathode pad. In certain embodiments, the thermal throttling device is configured to increase the resistance of the thermal throttling device based on an increase in the temperature of the thermal throttling device. In certain embodiments, the thermal throttling device comprises a positive-temperature-coefficient thermistor, a resettable fuse, or a memristor. In certain embodiments, the thermal throttling device is configured to decrease the resistance of the thermal throttling device based on an increase in the temperature of the thermal throttling device. In certain embodiments, the thermal throttling device comprises a negative-temperature-coefficient thermistor.

In another aspect, an LED package comprises: a support element comprising anode and cathode connections; an LED chip mounted to the support element and electrically coupled to the anode and cathode connections; and a thermal throttling device electrically coupled to at least one of the anode and cathode connections, the thermal throttling device being configured to have a resistance that changes based on a temperature of the thermal throttling device. In certain embodiments, the thermal throttling device is configured to reduce current flow through the LED chip when the temperature reaches a threshold temperature. In certain embodiments, the support element comprises a submount, and the anode and cathode connections comprise electrically conductive traces on a first side of the submount. In certain embodiments, the thermal throttling device comprises a patterned trace positioned between the submount and at least one of the anode connection and the cathode connection. In certain embodiments, the thermal throttling device comprises a portion of a patterned trace that also forms the anode connection or the cathode connection. The LED package may further comprise package bond pads on a second side of the submount that is opposite the first side, wherein the thermal throttling device comprises a via that extends through the submount. In certain embodiments, the thermal throttling device is configured to increase the resistance of the thermal throttling device based on an increase in the temperature of the thermal throttling device. In certain embodiments, the thermal throttling device comprises a positive-temperature-coefficient thermistor, a resettable fuse, or a memristor. In certain embodiments, the thermal throttling device is configured to decrease the resistance of the thermal throttling device based on an increase in the temperature of the thermal throttling device and form a shunt path for current flow to bypass an active LED structure of the LED chip. The LED package may further comprise an encapsulant covering the LED chip and at least a portion of the support element. In certain embodiments: the LED chip is a first LED chip, and a second LED chip is mounted to the support element and electrically coupled to the anode and cathode connections; the first LED chip and the second LED chip are electrically connected in series; and the thermal throttling device is a first thermal throttling device integrated with the first LED chip, and a second thermal throttling device is integrated with the second LED chip. In certain embodiments: the LED chip is a first LED chip, and a second LED chip is mounted to the support element and electrically coupled to the anode and cathode connections; and the thermal throttling device is configured to reduce current flow to both the first LED chip and the second LED chip when the temperature reaches a threshold temperature.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) chip with integrated chip-level thermal throttling according to aspects of the present disclosure.

FIG. 2 is a circuit diagram generally representing the LED chip of FIG. 1.

FIG. 3 is a cross-sectional view of an LED package with package-level integrated thermal throttling according to aspects of the present disclosure.

FIG. 4 is a cross-sectional view of an LED package with integrated chip-level and package-level thermal throttling according to principles of the present disclosure.

FIG. 5 is a cross-sectional view of an LED package that includes the LED chip of FIG. 1 according to principles of the present disclosure.

FIG. 6 is a cross-sectional view of an LED package similar to the LED package of FIG. 5 except the thermal throttling device is positioned along a different portion of the support element.

FIG. 7 is a cross-sectional view of an LED package similar to the LED package of FIG. 6 but with an alternative configuration of the thermal throttling device.

FIG. 8 is a cross-sectional view of an LED package similar to the LED package of FIG. 5 for multiple-chip embodiments.

FIG. 9 is a cross-sectional view of an LED package similar to the LED package of FIG. 8 except the thermal throttling device is formed in a manner similar to FIG. 3.

FIG. 10 is a top view of an LED package similar to the LED package of FIG. 8 for a large array of LED chips.

FIG. 11 is a cross-sectional view of an LED chip similar to the LED chip of FIG. 1 with integrated chip-level thermal throttling in parallel arrangements according to aspects of the present disclosure.

FIG. 12 is a circuit diagram generally representing the LED chip of FIG. 11.

FIG. 13 is a cross-sectional view of an LED package with package-level integrated thermal throttling in parallel arrangements according to aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to integrated thermal throttling in LED chips and LED packages. Thermal throttling devices are integrated as part of electrically conductive pathways within LED chips and/or within LED packages. When temperature conditions rise above certain thresholds, integrated thermal throttling devices reduce and/or halt current flow, thereby avoiding overheating of LED chips and LED packages. Thermal throttling devices may be positioned proximate anode and/or cathode pads at a chip-level and/or proximate anode and/or cathode connections at a package-level. With such integration, LED chips and LED packages may exhibit self-protection against excess temperature operating conditions.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480nm. In other embodiments, the active LED structure emits green light with a peak wavelength range of 500nm to 570nm. In other embodiments, the active LED structure emits red light with a peak wavelength range of 600nm to 700nm. In certain embodiments, the active LED structure may be configured to emit light that is outside the visible spectrum, including one or more portions of the ultraviolet (UV) spectrum (e.g., 100nm to 400nm), or one or more portions of the near infrared spectrum, and/or the infrared spectrum (e.g., 700nm to 1000nm).

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount or a lead frame structure.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Lead frame structures typically include electrically conductive leads that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

Encapsulant materials, such as silicone, epoxy, or polymethyl methacrylate (PMMA), among others, may be formed to encapsulate the LED chips over a submount or a lead frame structure. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

LED devices, such as LED chips and LED packages, are susceptible to damage and/or impaired operation with excess heat. Heat may be generated by the LED device in an event where excess current is supplied or from external factors such as other nearby electronic devices or the surrounding environment. In instances where the LED device is exposed to excess heat, turning the LED device off until the excess heat has dissipated may reduce any damaging effects to the LED chip and/or elements of the LED package such as a silicone lens. Operating temperature parameters may be determined by reliability testing and are dependent on specific LED chip and package structures as well as materials present. Product data sheets typically provide end users with recommended operating temperature windows and thresholds.

According to principles of the present disclosure, thermal throttling devices are integrated in LED chips and/or LED packages that are configured to provide protection against excess heat. Relative resistance of a thermal throttling device is configured to change in response to changes in temperature of the thermal throttling device. Thermal throttling devices are strategically positioned close to active LED structures of LED chips and/or various elements of an LED package to ensure precise temperature monitoring. Exemplary thermal throttling devices include a thermistor, a memristor, and/or a resettable fuse such as a polyfuse or a multifuse designed to limit or stop the flow of current to the LED chip to protect the LED chip from overheating and/or attempting to run outside of its recommended operating temperature parameters.

In certain embodiments, the thermal throttling device is configured to increase its resistance in response to increased temperature. For example, the thermal throttling device may embody a positive-temperature-coefficient (PTC) thermistor that exhibits increased resistance with increased temperature due to changes in charge carrier effects of semiconductor materials. In another example, the thermal throttling device may embody a resettable fuse, such a polyfuse or a multifuse, that exhibits increased resistance with increased temperature due to structural changes, such as disruptions to thermal pathways of a material like carbon black due to thermal expansion. In another example, the thermal throttling device may embody a memristor made through a variety of materials and mechanisms such as a polymeric memristor that exhibits conformation charge where conductive groups are aligned under current and may be reset at temperatures above the glass transition of the polymer for increased resistance. In other embodiments, the thermal throttling device is configured to decrease its resistance in response to increased temperature. For example, the thermal throttling device may embody a negative-temperature-coefficient (NTC) thermistor where resistance decreases with increased temperature due to changes in charge carrier effects such as valence electrons moving to the conduction band with increased thermals.

FIG. 1 is a cross-sectional view of an LED chip 10 with integrated chip-level thermal throttling according to aspects of the present disclosure. The LED chip 10 generally includes an active LED structure 12 configurated to generate light when electrically activated. In certain embodiments, the active LED structure 12 is supported by a substrate 14, such as a growth substrate or a carrier substrate to which the active LED structure 12 has been transferred. In other embodiments, the substrate 14 may be omitted. The LED chip 10 includes an anode pad 16 and a cathode pad 18 that are electrically coupled to the active LED structure 12. The anode pad and the cathode pad 18 may each comprise a single metal layer or a multiple-layer metal stack that may provide electrical contacts for receiving electrical connections external to the LED chip 10.

The LED chip 10 further includes at least one thermal throttling device 20 configured to change its resistance based on a temperature of the thermal throttling device 20. In certain embodiments, the thermal throttling device 20 is positioned as part of an electrically conductive path between the anode pad 16 and the active LED structure 12 and/or an electrically conductive path between the cathode pad 18 and the active LED structure 12. In such a position, the thermal throttling device 20 is in close proximity to the LED structure 12 so that a temperature of the thermal throttling device 20 would be very close if not the same as the active LED structure 12. When the temperature of the thermal throttling device 20 reaches a predetermined threshold temperature indicative of potential damage to the LED chip 10 and/or other elements the LED chip 10 is positioned near, current flow to the active LED structure 12 may be reduced and/or stopped. Once the temperature falls below the threshold temperature, the resistance of the thermal throttling device 20 will reduce and normal current flow through the active LED structure 12 may resume. Each thermal throttling device 20 may be integrated within the LED chip 10 by way of patterned deposition in a similar manner as the anode and cathode pads 16, 18. In this regard, the thermal throttling device may have a same or similar width as the corresponding anode pad 16 or cathode pad 18.

While two thermal throttling devices 20 are illustrated in FIG. 1, the principles are applicable to a single thermal throttling device 20 at either the anode pad 16 or the cathode pad 18. Moreover, the LED chip 10 is shown as a flip-chip where the anode pad 16 and the cathode pad 18 are positioned to be mounted and electrically connected to another surface, such as a support structure of an LED package or a printed circuit board of a larger device. It is understood that the principles described with respect to the thermal throttling device 20 are applicable to other chip structures, such as vertical chips and lateral chips that receive one or more topside wire bonds.

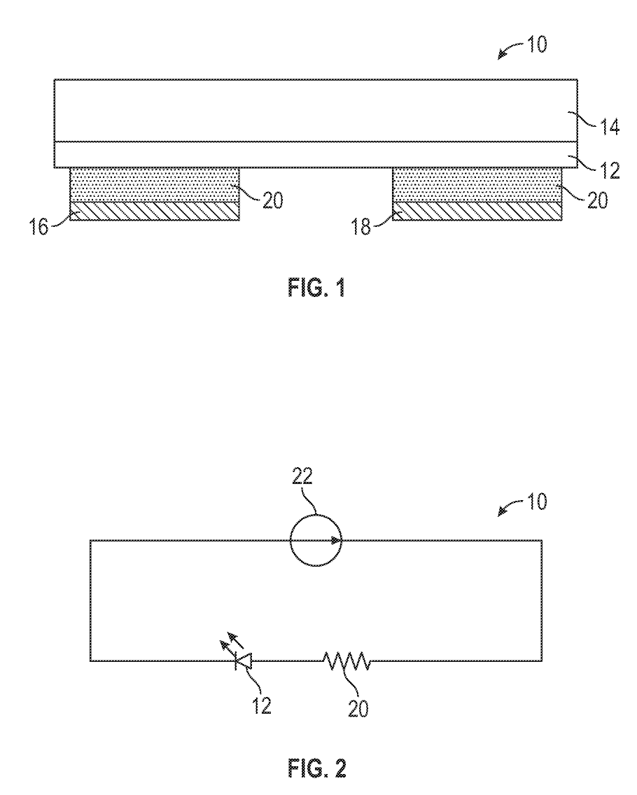

FIG. 2 is a circuit diagram generally representing the LED chip 10 of FIG. 1. A current source 22 is illustrated for producing current flow to the active LED structure 12 and the thermal throttling device 20. It is appreciated that the principles described herein are equally applicable to replacing the current source 22 with a voltage source. As illustrated, the thermal throttling device 20 and the active LED structure 12 are serially connected in the arrangement of FIG. 1. Under normal operation, the resistance of the thermal throttling device 20 is low, thereby permitting normal current flow through the LED chip 10 and corresponding active LED structure 12. When the temperature of the thermal throttling device 20 reaches a predetermined threshold temperature, the resistance of the thermal throttling device 20 will increase. Once the overall system reaches a compliance voltage, the current flow will drop and/or stop, thereby providing thermal protection for the LED chip 10. When the temperature drops below the threshold temperature, the resistance of the thermal throttling device 20 will decrease and permit normal operation to resume. Accordingly, operation of the LED chip 10 at excess temperatures is avoided, thereby reducing the likelihood of irreparable damage or failure.

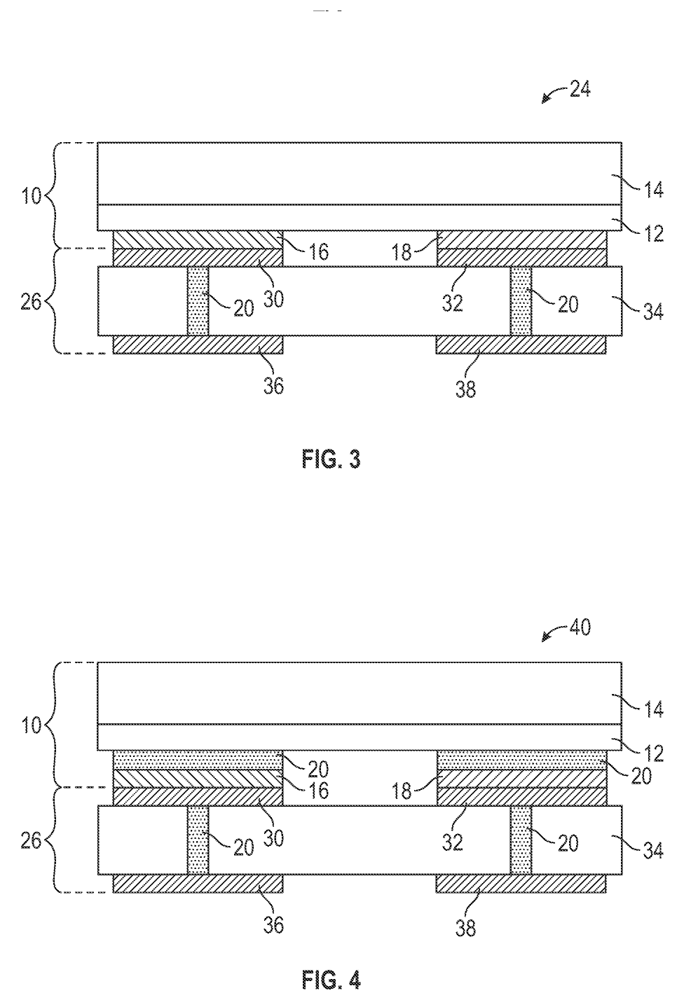

FIG. 3 is a cross-sectional view of an LED package 24 with package-level integrated thermal throttling according to aspects of the present disclosure. The LED package 24 includes the LED chip 10 mounted to a support element 26. The support element 26 may embody a sub mount structure or a lead frame structure. The support element 26 includes an anode connection 30 and a cathode connection 32 positioned to respectively receive the anode pad 16 and the cathode pad 18 of the LED chip 10. The anode and cathode connections 30, 32 may embody electrically conductive traces that reside on a first side of a sub mount 34 of the support element 26. Corresponding package bond pads 36, 38 may be provided on an opposing side of the sub mount 34 for mounting and electrically coupling the LED package 24 as part of a larger device. The thermal throttling device 20 may be positioned as part of the electrically conductive path between the anode connection 30 and corresponding package bond pad 36, and another thermal throttling device 20 may be positioned as part of the electrically conductive path between the cathode connection 32 and corresponding package bond pad 38. In certain embodiments, the thermal throttling devices 20 may embody vias that extend through the sub mount 34. Operation of the LED package 24 may be similar to the circuit diagram of FIG. 2. For example, under normal operation, the resistance of the thermal throttling devices 20 is low enough to permit normal current flow. When the temperature exceeds a threshold temperature, the resistance of the thermal throttling devices 20 increases, thereby limiting and/or stopping current flow to the LED chip 10 and the active LED structure 12.

FIG. 4 is a cross-sectional view of an LED package 40 with integrated chip-level and package-level thermal throttling according to principles of the present disclosure. The LED package 40 may comprise the LED chip 10 of FIG. 1 that includes one or more thermal throttling devices 20 between the active LED structure 12 and the anode and/or cathode pads 16, 18. The LED package 40 may further comprise the support element 26 of FIG. 3 with additional one or more thermal throttling devices 20. Accordingly, normal current flow for the LED chip 10 and active LED structure 12 may be lowered or halted based on temperature increases above threshold temperatures in areas proximate or immediately adjacent the active LED structure 12 and also in areas within the support element 26.

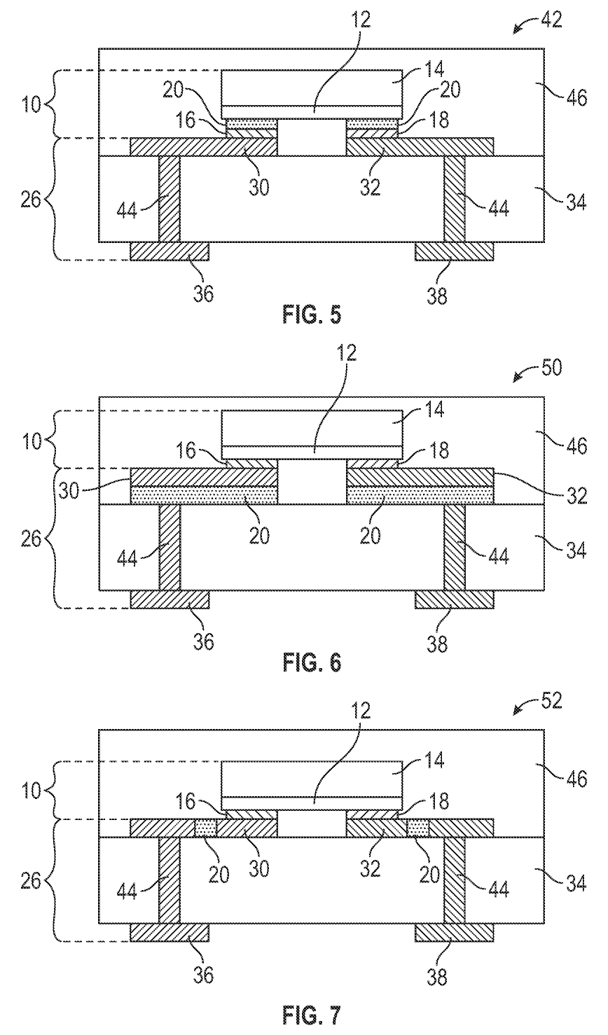

FIG. 5 is a cross-sectional view of an LED package 42 that includes the LED chip 10 of FIG. 1 according to principles of the present disclosure. The LED package 42 includes the support element 26 as previously described with respect to FIG. 3 except electrically conductive vias 44 without thermal throttling capabilities reside within the sub mount 34. The LED chip 10 includes the integrated thermal throttling device 20 as described above for FIG. 1. The LED package 42 further includes an encapsulant 46 that covers the LED chip 10 and at least a portion or even all of the top surface of the support element 26. The encapsulant 46 may comprise silicone or epoxy. In further embodiments, the encapsulant 46 comprises a lumiphoric material configured for wavelength conversion of light from the LED chip 10.

FIG. 6 is a cross-sectional view of an LED package 50 similar to the LED package 42 of FIG. 5 except the thermal throttling device 20 is positioned along a different portion of the support element 26. In FIG. 6, the thermal throttling device 20 is positioned on a top surface of the sub mount 34 as part of the topside patterned traces. In certain embodiments, the thermal throttling device 20 is positioned as a patterned trace between the anode connection 30 and the via 44 that extends through the sub mount 34 and/or between the cathode connection 32 and the corresponding via 44 that extends through the sub mount 34. Each thermal throttling device 20 may be patterned on a top side of the sub mount 34 in a manner similar to the anode and cathode connections 30, 32. In such a configuration, each thermal throttling device 20 may laterally extend on the sub mount 34 away from the LED chip 10.

FIG. 7 is a cross-sectional view of an LED package 52 similar to the LED package 50 of FIG. 6 but with an alternative configuration of the thermal throttling device 20. In FIG. 7, the thermal throttling device 20 is integrated with the anode connection 30 and/or the cathode connection 32. For example, the thermal throttling device 20 may form part of the patterned trace that also forms the anode connection 30 and/or the cathode connection 32 for electrically connecting the anode and/or cathode bond pads 16, 18 to corresponding vias 44.

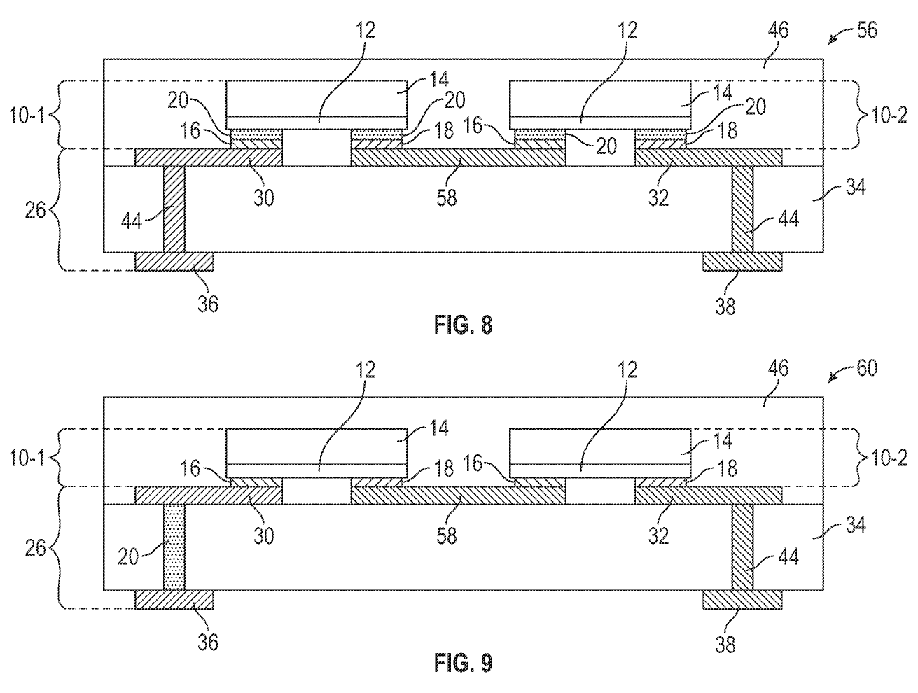

FIG. 8 is a cross-sectional view of an LED package 56 similar to the LED package 42 of FIG. 5 for multiple-chip embodiments. For illustrative purposes, the LED package 56 is shown with two LED chips 10-1 to 10-2; however, a total number of LED chips 10-1 to 10-2 may be larger in various applications. In certain embodiments, the LED chips 10-1 to 10-2 are electrically coupled in series by way of a bus connection 58. For example, the bus connection 58 may be formed as another electrical trace on the sub mount 34 concurrently with the anode and cathode connections 30, 32. The bus connection 58 may electrically couple the cathode pad 18 of the first LED chip 10-1 to the anode pad 16 of the second LED chip 10-2. Since thermal throttling devices are present in both serially connected LED chips 10-1, 10-2, an excess temperature condition for a single one of the LED chips 10-1, 10-2 may reduce and/or halt current flow for both LED chips 10-1, 10-2 for added thermal protection.

FIG. 9 is a cross-sectional view of an LED package 60 similar to the LED package 56 of FIG. 8 except the thermal throttling device 20 is formed in a manner similar to FIG. 3. For example, the thermal throttling device 20 is formed to extend through the sub mount 34 between the anode connection 30 and corresponding package bond pad 36. Accordingly, the thermal throttling device 20 may form a via through the sub mount 34. In certain embodiments, the same thermal throttling device 20 is used for the multiple LED chips 10-1, 10-2. Since the LED chips 10-1, 10-2 are electrically coupled in series, increased resistance at the single thermal throttling device 20 may reduce and/or halt current flow for both LED chips 10-1, 10-2 for added thermal protection.

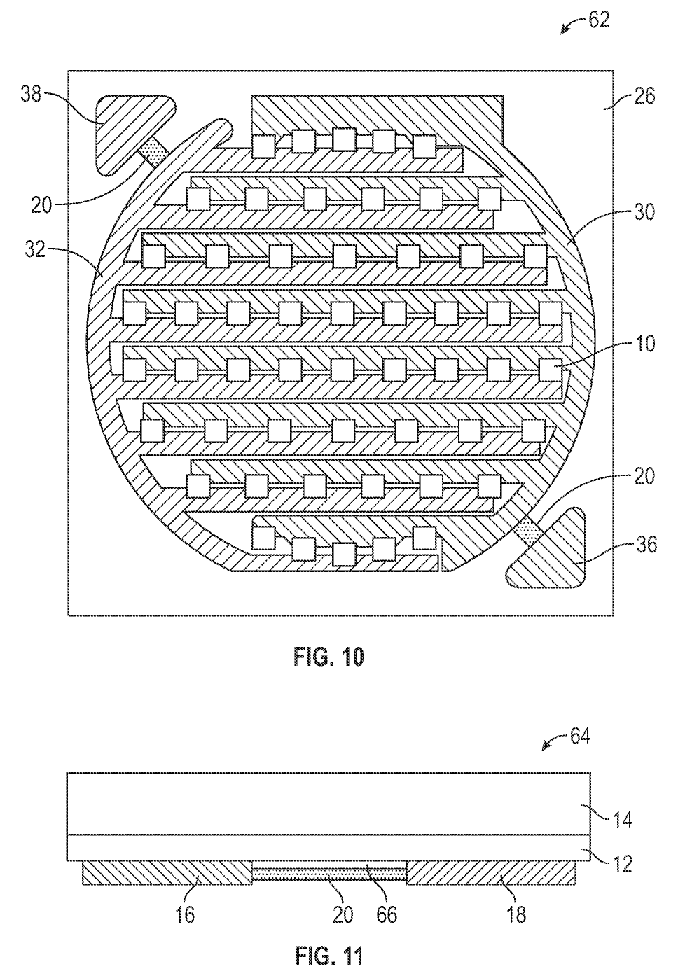

FIG. 10 is a top view of an LED package 62 similar to the LED package 56 of FIG. 8 for a large array of LED chips 10. The anode connection 30 and the cathode connection 32 form two patterned traces on a top side of the sub mount 34. The anode connection 30 and the cathode connection 32 each form a number of extensions that are interdigitated with one another to provide multiple die attach areas for the LED chips 10. As illustrated, each LED chip 10 is mounted and electrically connected to the anode connection 30 and the cathode connection 32. Such an arrangement is similar to the flip-chip configuration of the LED chip 10 of FIG. 7. In FIG. 10, the package bond pads 36, 38 are positioned on the same top side as the anode connection 30, the cathode connection 32, and the LED chips 10. This facilitates topside electrical contacts to the package bond pads 36, 38 by way of wire bonds. The thermal throttling device 20 may be formed to connect the anode connection 30 to the corresponding package bond pad 36 and/or to connect the cathode connection 32 to the corresponding package bond pad 38. The thermal throttling device 20 may therefore form part of a patterned trace that also includes the anode connection 30 and the package bond pad 36. Alternatively, or in addition to, the thermal throttling device 20 may form part of a patterned trace that also includes the cathode connection 32 and the package bond pad 38. An excess temperature condition at either thermal throttling device 20 may accordingly reduce and/or halt current flow to the entire array of LED chips 10.

While various examples have been described with thermal throttling devices serially connected with active LED structures as illustrated in FIG. 2, the principles described are also appliable to other LED chip and LED package arrangements. For example, thermal throttling devices may be integrated in LED chips and/or LED packages in parallel with active LED structures. In such configurations, the thermal throttling devices may be configured to have high resistances at normal operating conditions so that current flows normally through the active LED structure. When operating conditions exceed designated threshold temperatures, the thermal throttling devices may decrease resistance to the level where current flow predominately bypasses the active LED structure and instead flows through the thermal throttling devices. As described above, examples of such thermal throttling device include NTC thermistors integrated in LED chips and/or LED packages.

FIG. 11 is a cross-sectional view of an LED chip 64 similar to the LED chip 10 of FIG. 1 with integrated chip-level thermal throttling in parallel arrangements according to aspects of the present disclosure. As illustrated, the thermal throttling device 20 may be formed to connect between the anode pad 16 and the cathode pad 18 in a parallel manner with the active LED structure 12. In certain embodiments, an insulating layer 66 may be provided between the thermal throttling device 20 and the active LED structure 12. The thermal throttling device 20 in FIG. 11 is configured to decrease resistance above a threshold temperature for the LED chip 64. During operation at normal temperature ranges, the resistance of the thermal throttling device 20 is such that current is directed through the active LED structure 12 to electrically activate the LED chip 64. When the threshold temperature is reached or exceeded, the resistance of the thermal throttling device 20 decreases below that of the active LED structure 12, thereby creating a shunt path that reduces and/or halts current flow through the active LED structure 12.

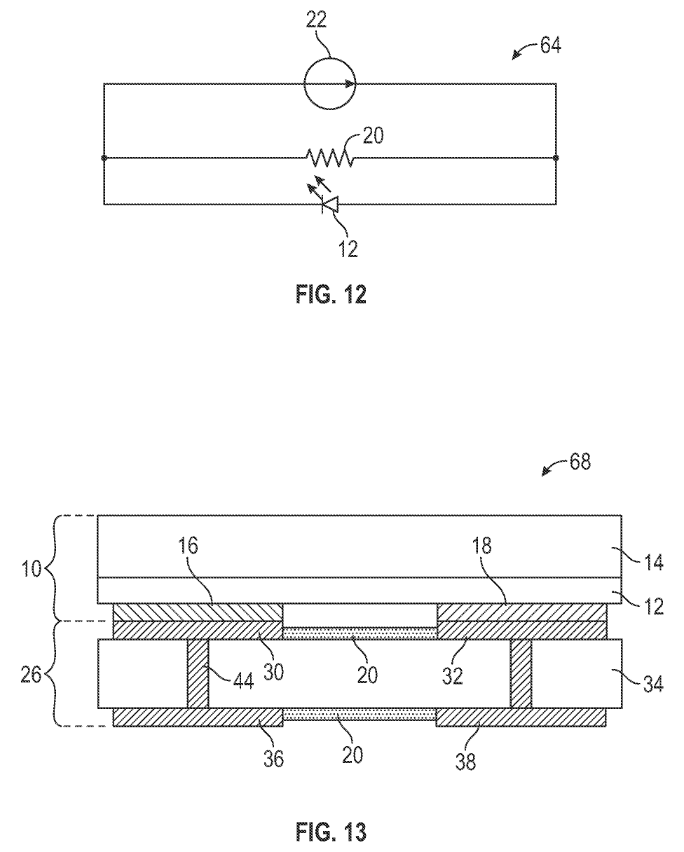

FIG. 12 is a circuit diagram generally representing the LED chip 64 of FIG. 11. The current source 22 is illustrated for producing current flow to the active LED structure 12. It is appreciated that the principles described herein are equally applicable to replacing the current source 22 with a voltage source. As illustrated, the thermal throttling device 20 and the active LED structure 12 are connected in a parallel arrangement. At normal operating temperatures, the resistance of the thermal throttling device 20 is greater than the resistance of the active LED structure 12, thereby permitting normal current flow through the active LED structure 12. When the operating temperature exceeds a threshold temperature, the resistance of the thermal throttling device 20 is reduced to lower than that of the active LED structure 12, thereby forming a shunt path bypassing the active LED structure 12. After a period of time when the temperature reduces below the threshold, the resistance of the thermal throttling device 20 may increase again and the active LED structure may be electrically activated to resume normal operation.

FIG. 13 is a cross-sectional view of an LED package 68 with package-level integrated thermal throttling in parallel arrangements according to aspects of the present disclosure. Operation of the LED package 68 may be similar to the circuit diagram of FIG. 12. As illustrated, the thermal throttling device 20 may be electrically connected between the anode connection 30 and the cathode connection 32 on the top side of the sub mount 34. At normal operating temperatures, the resistance of the thermal throttling device 20 is higher than that of the active LED structure 12, thereby directing current flow through the active LED structure 12. At temperatures above threshold, the resistance of the thermal throttling device drops below that of the active LED structure 12, thereby opening a shunt path that bypasses and/or directs current through thermal throttling device 20. In certain embodiments, the thermal throttling device 20 may be located on the bottom side of the sub mount 34 and electrically connected between the package bond pads 36 and 38, thereby creating a shunt path at excess temperatures. In certain embodiments, thermal throttling devices 20 may be present on both the top side and the bottom side of the sub mount 34 as illustrated in FIG. 13. Alternatively, a single thermal throttling device 20 may be present, either on the top side or on the bottom side of the sub mount 34.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
an active LED structure;
an anode pad and a cathode pad on the active LED structure; and
a thermal throttling device on the active LED structure and electrically coupled to the anode pad or the cathode pad, the thermal throttling device being configured to have a resistance that changes based on a temperature of the thermal throttling device.

2. The LED package of claim 1, wherein the thermal throttling device is configured to reduce current flow through the LED chip when the temperature reaches a threshold temperature.

3. The LED chip of claim 1, wherein the thermal throttling device is positioned between the active LED structure and either the anode pad or the cathode pad.

4. The LED chip of claim 1, wherein the thermal throttling device is a first thermal throttling device positioned between the active LED structure and the anode pad, and a second thermal throttling device is positioned between the active LED structure and the cathode pad.

5. The LED chip of claim 1, wherein the thermal throttling device is configured to increase the resistance of the thermal throttling device based on an increase in the temperature of the thermal throttling device.

6. The LED chip of claim 5, wherein the thermal throttling device comprises a positive-temperature-coefficient thermistor, a resettable fuse, or a memristor.

7. The LED chip of claim 1, wherein the thermal throttling device is configured to decrease the resistance of the thermal throttling device based on an increase in the temperature of the thermal throttling device.

8. The LED chip of claim 7, wherein the thermal throttling device comprises a negative-temperature-coefficient thermistor.

9. A light-emitting diode (LED) package comprising:
a support element comprising anode and cathode connections;
an LED chip mounted to the support element and electrically coupled to the anode and cathode connections; and
a thermal throttling device electrically coupled to at least one of the anode and cathode connections, the thermal throttling device being configured to have a resistance that changes based on a temperature of the thermal throttling device.

10. The LED package of claim 9, wherein the thermal throttling device is configured to reduce current flow through the LED chip when the temperature reaches a threshold temperature.

11. The LED package of claim 9, wherein the support element comprises a submount, and the anode and cathode connections comprise electrically conductive traces on a first side of the submount.

12. The LED package of claim 11, wherein the thermal throttling device comprises a patterned trace positioned between the submount and at least one of the anode connection and the cathode connection.

13. The LED package of claim 11, wherein the thermal throttling device comprises a portion of a patterned trace that also forms the anode connection or the cathode connection.

14. The LED package of claim 11, further comprising package bond pads on a second side of the submount that is opposite the first side, wherein the thermal throttling device comprises a via that extends through the submount.

15. The LED package of claim 9, wherein the thermal throttling device is configured to increase the resistance of the thermal throttling device based on an increase in the temperature of the thermal throttling device.

16. The LED package of claim 15, wherein the thermal throttling device comprises a positive-temperature-coefficient thermistor, a resettable fuse, or a memristor.

17. The LED package of claim 9, wherein the thermal throttling device is configured to decrease the resistance of the thermal throttling device based on an increase in the temperature of the thermal throttling device and form a shunt path for current flow to bypass an active LED structure of the LED chip.

18. The LED package of claim 9, further comprising an encapsulant covering the LED chip and at least a portion of the support element.

19. The LED package of claim 9, wherein:
the LED chip is a first LED chip, and a second LED chip is mounted to the support element and electrically coupled to the anode and cathode connections;
the first LED chip and the second LED chip are electrically connected in series; and
the thermal throttling device is a first thermal throttling device integrated with the first LED chip, and a second thermal throttling device is integrated with the second LED chip.

20. The LED package of claim 9, wherein:
the LED chip is a first LED chip, and a second LED chip is mounted to the support element and electrically coupled to the anode and cathode connections; and
the thermal throttling device is configured to reduce current flow to both the first LED chip and the second LED chip when the temperature reaches a threshold temperature.
